(19) United States
(12) Patent Application Publication
(10) Pub. No.: US 2015/0097275 A1
(43) Pub. Date: Apr. 9, 2015

(54) SEMICONDUCTOR DEVICE AND MANUFACTURING METHOD OF SEMICONDUCTOR DEVICE

(71) Applicant: TOYOTA JIDOSHA KABUSHIKI KAISHA, Toyota-shi (JP)

(72) Inventors: Atsushi IMAI, Toyota-shi (JP); Yoshiaki KOMINAMI, Nagakute-shi (JP); Takashi USHIJIMA, Nagoya-shi (JP)

(21) Appl. No.: 14/500,179

(22) Filed: Sep. 29, 2014

(30) Foreign Application Priority Data
Oct. 8, 2013 (JP) 2013-210967

(51) Int. Cl. H01L 29/06; H01L 21/288; H01L 21/283; H01L 29/41

(52) U.S. Cl. CPC H01L 29/0657; H01L 29/41; H01L 21/288; H01L 21/283
USPC 257/623; 438/652

(57) ABSTRACT

A semiconductor device includes a substrate, a substrate-side electrode layer, an intermediate electrode layer, and a front-side electrode layer. The substrate includes a semiconductor layer and a projection portion, the projection portion being formed on a surface of the semiconductor layer. The substrate-side electrode layer is provided on the projection portion. The intermediate electrode layer extends from on a part of the substrate-side electrode layer, which part of the substrate-side electrode layer is located on the projection portion, to just above a region of the substrate in which region the projection portion is not provided. The front-side electrode layer is provided on a surface of the intermediate electrode layer. A Young's modulus E1 of the substrate-side electrode layer, a Young's modulus E2 of the intermediate electrode layer, and a Young's modulus E3 of the front-side electrode layer satisfy a relationship of E3>E1>E2.

### INCORPORATION BY REFERENCE

The disclosure of Japanese Patent Application No. 2013-210967 filed on Oct. 8, 2013 including the specification, drawings and abstract is incorporated herein by reference in its entirety.

### BACKGROUND OF THE INVENTION

1. Field of the Invention

The present invention relates to a semiconductor device and a manufacturing method of a semiconductor device.

2. Description of Related Art

Japanese Patent Application Publication No. 2010-272711 (JP 2010-272711 A) describes a substrate including two passivation films having a projection shape on a surface thereof. An electrically-conductive layer is formed on the passivation films so as to extend over a region between the passivation films.

Generally, an outermost electrode layer among electrodes in a semiconductor device is hard. In a case where such a hard metal layer is placed in vicinity to a projection portion (e.g., the passivation film in JP 2010-272711 A) on a surface of a substrate, when heat is applied to the semiconductor device from outside in a mounting step of the semiconductor device, for example, a high stress is applied to the projection portion, which may affect performance of the projection portion.

### SUMMARY OF THE INVENTION

The present invention provides a semiconductor device in which a projection portion is hard to receive a stress, and a manufacturing method of the semiconductor device.

A semiconductor device according to a first aspect of the present invention includes a substrate, a substrate-side electrode layer, an intermediate electrode layer, and a front-side electrode layer. The substrate includes a semiconductor layer and a projection portion, the projection portion being formed on a surface of the semiconductor layer. The substrate-side electrode layer is provided on the projection portion. The intermediate electrode layer extends from on a part of the substrate-side electrode layer, which part of the substrate-side electrode layer is located on the projection portion, to just above a region of the substrate in which the projection portion is not provided. The front-side electrode layer is provided on a surface of the intermediate electrode layer. A Young's modulus E1 of the substrate-side electrode layer, a Young's modulus E2 of the intermediate electrode layer, and a Young's modulus E3 of the front-side electrode layer satisfy a relationship of E3>E1>E2.

Note that the substrate should have a semiconductor layer, and the substrate may have an insulating layer as well as the semiconductor layer. Further, the projection portion may be a semiconductor layer, or may be an insulating layer.

In the semiconductor device, the intermediate electrode layer is placed between the substrate-side electrode layer and the front-side electrode layer. A material of the intermediate electrode layer can be selected relatively freely. Accordingly, it is possible to employ a material having a low Young's modulus for the intermediate electrode layer. When the intermediate electrode layer having a low Young's modulus is provided between the substrate-side electrode layer and the front-side electrode layer, it is possible to restrain a high stress from being applied to the projection portion from the front-side electrode layer.

Note that, in the semiconductor device, the substrate-side electrode layer may be provided only on the projection portion, and may not be provided outside the projection portion (that is, just above that region of the substrate in which region the projection portion is not provided). Further, the substrate-side electrode layer may be provided so as to extend from above the projection portion to outside the projection portion.

In the semiconductor device of the first aspect of the present invention, the intermediate electrode layer may be provided in a lateral side of the projection portion. Further, a distance between the surface of the semiconductor layer and the surface of the intermediate electrode layer provided in the lateral side of the projection portion may be larger than a height of the projection portion from the surface of the semiconductor layer.

According to the above configuration, in a range where the intermediate electrode layer is placed, it is possible to prevent the front-side electrode layer from getting into the lateral side of the projection portion. This makes it possible to further reduce a stress to be applied, to the projection portion.

In the semiconductor device of the first aspect of the present invention, a recessed portion of the substrate-side electrode layer may be formed in the lateral side of the projection portion. Further, a width of the recessed portion may be smaller than twice a thickness of a part of the intermediate electrode layer, the part of the intermediate electrode layer being arranged just above the projection portion.

According to the above configuration, it is possible to easily fill the recessed portion of the substrate-side electrode layer with the intermediate electrode layer in a manufacturing process.

A semiconductor device according to a second aspect of the present invention includes a substrate, a substrate-side electrode layer, and a front-side electrode layer. The substrate includes a semiconductor layer and a projection portion, the projection portion being formed on a surface of the semiconductor layer. The substrate-side electrode layer extends from on the projection portion to just above a region of the substrate in which region the projection portion is not provided. The front-side electrode layer is provided on the substrate-side electrode layer and has a Young's modulus larger than a Young's modulus of the substrate-side electrode layer. The substrate-side electrode layer includes a first portion and a second portion in an end of the substrate-side electrode layer in a surface direction of the substrate. The first portion has a first thickness. The second portion has a second thickness smaller than the first thickness. The second portion is provided outside the first portion in the surface direction.

A semiconductor device according to a third aspect of the present invention includes a substrate, a substrate-side electrode layer, a front-side electrode layer, and an insulating layer. The substrate includes a semiconductor layer and a projection portion, the projection portion being formed on a surface of the semiconductor layer. The substrate-side electrode layer extends from on the projection portion to just above a region of the substrate in which region the projection portion is not provided. The front-side electrode layer is provided on the substrate-side electrode layer and has a Young's modulus larger than a Young's modulus of the substrate-side electrode layer. A front surface of the insulating layer and a back surface of the insulating layer are covered with the substrate-side electrode layer.

According to the semiconductor devices of the second and third aspects of the present invention, it is possible to reduce a stress to be applied to the projection portion in a similar way as the first aspect of the present invention.

A fourth aspect of the present invention is a manufacturing method of a semiconductor device. The manufacturing method includes: forming a substrate-side electrode layer on a projection portion of a substrate, the substrate including a semiconductor layer and the projection portion, the projection portion being formed on a surface of the semiconductor layer; forming an intermediate electrode layer that extends from on a part of the substrate-side electrode layer, which part of the substrate-side electrode layer is located on the projection portion, to just above a region of the substrate in which region the projection portion is not provided; and forming a front-side electrode layer on the intermediate electrode layer. A Young's modulus of the front-side electrode layer is higher than a Young's modulus of the intermediate electrode layer and a Young's modulus of the substrate-side electrode layer.

According to the manufacturing method, it is possible to manufacture the first, second, or third semiconductor device. That is, it is possible to restrain a stress to a projection in a semiconductor device to be manufactured.

In the manufacturing method of the fourth aspect of the present invention, the Young's modulus of the substrate-side electrode layer may be higher than the Young's modulus of the intermediate electrode layer.

According to the manufacturing method, it is possible to manufacture the semiconductor device according to the first aspect.

In the manufacturing method of the fourth aspect of the present invention, in the forming of the substrate-side electrode layer, any one of film forming methods consisting of spattering, deposition, plating, brush application, inkjet coating, and spray coating may be employed as a film forming method of an electrode material. Furthermore, in the forming of the substrate-side electrode layer, any one of patterning methods consisting of photolithography, liftoff, masking, and self-alignment may be employed as a patterning method. In the forming of the intermediate electrode layer, any one of the film forming methods and any one of the patterning methods may be employed. Furthermore, the forming of the substrate-side electrode layer and the forming of the intermediate electrode layer may be different from each other with respect to at least one of the film forming method and the patterning method.

According to the above manufacturing method, it is possible to reduce a possibility that similar abnormality occurs in a step of forming the substrate-side electrode layer and in a step of forming the intermediate electrode layer. Accordingly, it is possible to cover a whole region in which an electrode layer should be formed, with the substrate-side electrode layer or the intermediate electrode layer. Hereby, it is possible to restrain the front-side electrode layer from being formed in vicinity to the projection portion.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a drawing of a longitudinal section of a semiconductor device according to Embodiment 1 of the present invention;

FIG. 2 is a drawing of a longitudinal section of a semiconductor device according to Modification 1 of Embodiment 1;

FIG. 3 is a drawing of a longitudinal section of a semiconductor device according to Modification 2 of Embodiment 1;

FIG. 4 is a drawing of a longitudinal section of a semiconductor device according to Modification 3 of Embodiment 1;

FIG. 5 is a drawing of a longitudinal section of a semiconductor device according to Modification 4 of Embodiment 1;

FIG. 6 is a drawing of a longitudinal section of a semiconductor device according to Embodiment 2 of the present invention; and

FIG. 7 is a drawing of a longitudinal section of a semiconductor device according to Embodiment 3 of the present invention.

### DETAILED DESCRIPTION OF EMBODIMENTS

A semiconductor device of each embodiment described below has a feature in a structure of an electrode. Accordingly, the following description only deals with the structure of the electrode, and a description about a structure inside a semiconductor layer is omitted.

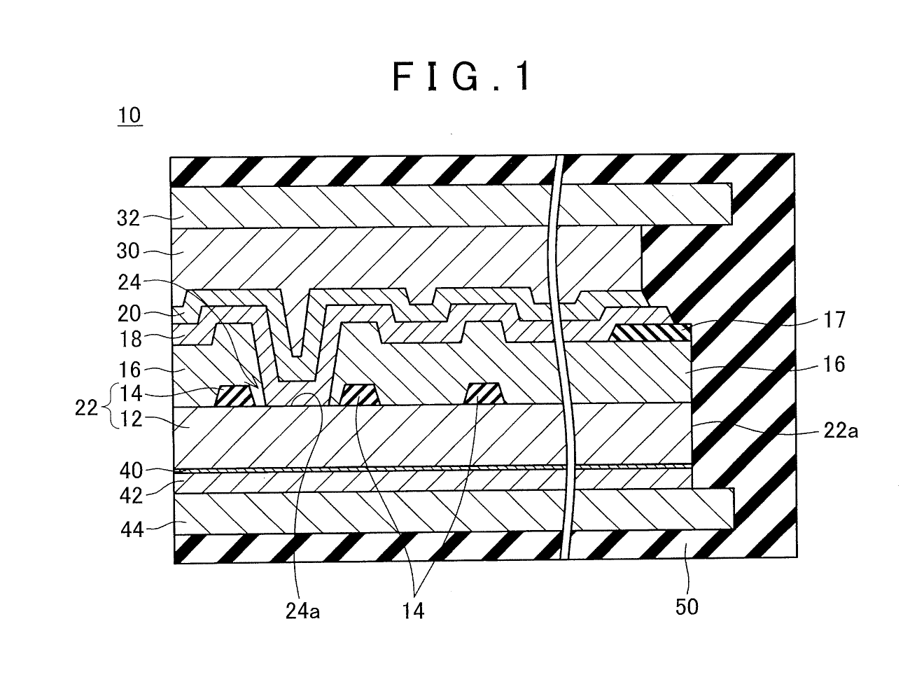

A semiconductor device 10 of Embodiment 1 illustrated in FIG. 1 includes a semiconductor layer 12, insulating layers 14, a substrate-side electrode layer 16, an intermediate electrode layer 18, and a front-side electrode layer 20, and so on. A surface of the semiconductor layer 12 is generally flat. A plurality of insulating layers 14 are formed on the surface of the semiconductor layer 12. The insulating layers 14 are each constitute a projection portion that projects from the surface of the semiconductor layer 12. In the following description, the semiconductor layer 12 and the insulating layers 14 are generally referred to as a substrate 22.

The substrate-side electrode layer 16 is formed generally in a whole surface of the substrate 22. Note that the substrate-side electrode layer 16 is not fainted in a part (a region 24a in FIG. 1) of the surface of the semiconductor layer 12 within a region 24 between two insulating layers 14 in FIG. 1. The region 24a where the substrate-side electrode layer 16 is not formed may be formed intentionally or may be formed unintentionally. The substrate-side electrode layer 16 is an electrode layer electrically connected to the semiconductor layer 12, and is made of Al or the like.

The intermediate electrode layer 18 is formed on a whole surface of the substrate-side electrode layer 16. Further, the intermediate electrode layer 18 is also formed on the region 24a. In the region 24a, the semiconductor layer 12 makes contact with the intermediate electrode layer 18. Note that, in the vicinity of an end 22a of the substrate 22, an insulating layer 17 is formed on the substrate-side electrode layer 16. In the vicinity of the end 22a, the intermediate electrode layer 18 is formed on the insulating layer 17.

The front-side electrode layer 20 is formed on a whole surface of the intermediate electrode layer 18. Note that the front-side electrode layer 20 may not be formed on the whole surface of the intermediate electrode layer 18, and may be formed in a part of the surface of the intermediate electrode layer 18. The front-side electrode layer 20 is connected to a lead frame 32 by a solder 30. The front-side electrode layer 20 is made of Ni, Cu, or the like so as to be joined to the solder 30.

The intermediate electrode layer 18 is an electrode layer that connects the front-side electrode layer 20 to the substrate-side electrode layer 16, and a material thereof can be selected relatively freely. A Young's modulus E1 of the substrate-side electrode layer 16, a Young's modulus E2 of the intermediate electrode layer 18, and a Young's modulus E3 of the front-side electrode layer 20 satisfy a relationship of E3>E1>E2. That is, the intermediate electrode layer 18 is made of a material having a Young's modulus lower than those of the substrate-side electrode layer 16 and the front-side electrode layer 20.

A back-surface electrode 40 is formed on a back surface of the substrate 22. The back-surface electrode 40 is connected to a lead frame 44 by a solder 42.

A resin layer 50 is formed around the semiconductor device 10. Note that the lead frames 32, 44 are drawn out of the resin layer 50 in a position not illustrated herein, and is electrically connectable to an external part.

In a mounting step of the semiconductor device 10, heat may be applied from outside to the semiconductor device 10. When heat is applied from outside to the semiconductor device 10, a stress is applied to the insulating layer 14 and the semiconductor layer 12 due to thermal expansion of the lead frames 32, 44 and the resin layer 50. Further, at the time of the use of the semiconductor device 10, the semiconductor device 10 generates heat. Since thermal expansion coefficients of respective materials are different from each other, when the semiconductor device 10 generates heat, a thermal stress is applied to the insulating layers 14 and the semiconductor layer 12. In such a state, if the hard front-side electrode layer 20 (that is, the Young's modulus is high) is provided in the vicinity of the insulating layer 14 having a projecting shape, a large stress is applied to the insulating layer 14. Particularly, if the hard front-side electrode layer 20 is provided in a lateral side of the insulating layer 14 (for example, within the region 24 between two insulating layers 14), there is a possibility that an large shear stress is applied to the insulating layer 14. On the other hand, in the semiconductor device 10, the soft intermediate electrode layer 18 (that is, the Young's modulus is low) is provided between the front-side electrode layer 20 and the insulating layer 14. Accordingly, the intermediate electrode layer 18 functions as a buffer, so that it is possible to restrain a high stress from being applied to the insulating layer 14. Further, in the region 24a between two insulating layers 14 where no substrate-side electrode layer 16 exists, the intermediate electrode layer 18 is formed thicker than the insulating layers 14. Because of this, no front-side electrode layer 20 exists in the region 24 between two insulating layers 14 (that is, in a lateral direction of the insulating layers 14). This prevents a high shear stress from being applied to the insulating layer 14. Accordingly, the semiconductor device 10 has a high reliability.

Next will be described a manufacturing method of the semiconductor device 10 of Embodiment 1. First, a plurality of insulating layers 14 is formed on a surface of a semiconductor layer 12 by any method well known in the art. Then, a substrate-side electrode layer 16 is formed. That is, the substrate-side electrode layer 16 is formed, and then patterning is performed to the substrate-side electrode layer 16. By performing the patterning, a region 24a where no substrate-side electrode layer 16 exists may be formed intentionally within a region 24 between two insulating layers 14. Further, in a step of forming the substrate-side electrode layer 16, the region 24a may be formed unintentionally. After the substrate-side electrode layer 16 is formed, an insulating layer 17 is formed along an end 22a of a substrate 22. Then, an intermediate electrode layer 18 is formed on a surface of the substrate including the substrate-side electrode layer 16 and the insulating layer 17. That is, the intermediate electrode layer 18 is formed, and then patterning is performed to the intermediate electrode layer 18. The intermediate electrode layer 18 is formed to be thicker than the insulating layers 14. Hereby, the intermediate electrode layer 18 is formed in the region 24a and on the substrate-side electrode layer 16. Then, a front-side electrode layer 20 is formed on the intermediate electrode layer 18. Since the intermediate electrode layer 18 is thicker than the insulating layers 14, the front-side electrode layer 20 does not get into the region 24 between two insulating layers 14 even on the region 24a. Hereby, a structure in which a high stress is hard to occur is obtained. After that, a back-surface electrode 40 is formed, and soldering to lead frames 32, 42 is performed. Then, a resin layer 50 is formed, and thus, the semiconductor device 10 is completed.

Note that, as described above, in the step of forming the substrate-side electrode layer 16, a region where no substrate-side electrode layer 16 exists may be formed. However, in the manufacturing method, a step of forming the intermediate electrode layer 18 is performed separately from the step of forming the substrate-side electrode layer 16. On that account, even if the region where no substrate-side electrode layer 16 exists may be formed unintentionally, the region is covered with the intermediate electrode layer 18. Thus, before forming the hard front-side electrode layer 20, the steps of forming the electrode layers 16, 18 that are softer than the front-side electrode layer 20 are performed several times, so that it is possible to prevent the hard front-side electrode layer 20 from being formed in proximity to the insulating layers 14 and the semiconductor layer 12. Note that, in the step of forming the substrate-side electrode layer 16, any of spattering, deposition, plating, brush application, inkjet coating, and spray coating can be employed as a film forming method, for example. Further, in the step of forming the substrate-side electrode layer 16, any of photolithography, liftoff, masking, and self-alignment can be employed as a patterning method, for example. Also in the step of forming the intermediate electrode layer 18, any one of the above film forming methods can be employed, and any one of the above patterning methods can be employed. Here, it is preferable that the step of forming the substrate-side electrode layer 16 and the step of forming the intermediate electrode layer 18 employ different methods for at least either of the film forming method and the patterning method. According to such a configuration, it is possible to more surely prevent the front-side electrode layer 20 from being formed in proximity to the insulating layers 14 and the semiconductor layer 12. That is, in each of the step of forming the substrate-side electrode layer 16 and the step of forming the intermediate electrode layer 18, a region where no electrode layer exists, like the region 24a, may be partially formed unintentionally. If such a region is formed in the same area in the substrate-side electrode layer 16 and in the intermediate electrode layer 18, the front-side electrode layer 20 gets into the region, which may cause a problem with stress. When the step of forming the substrate-side electrode layer 16 and the step of forming the intermediate electrode layer 18 employ different methods for at least either of the deposition method and the patterning method, it is possible to reduce such a possibility that the region where no electrode layer exists would be formed in the same area in these steps. Thus, according to the above manufacturing method, it is possible to more surely prevent the front-side electrode layer 20 from being formed in proximity to the insulating layers 14 and the semiconductor layer 12.

Note that the liftoff is the following technique. In the liftoff, a patterned soluble film (a film that can be dissolved later) is formed on a surface of a base member such as a substrate, before an electrode layer is formed. After that, an electrode layer is formed on a whole surface of the base member. The electrode layer is formed on the soluble film in an area where the soluble film exists, and the electrode layer is formed directly on the base member in an area where no soluble film is formed. Then, the soluble film is removed by etching or the like. Hereby, the electrode layer formed on the soluble film is removed, and only the electrode layer formed directly on the base member remains on the base member. Hereby, the electrode layer is patterned.

Further, the masking is the following technique. In the masking, a masking plate is provided on a surface of a base member before an electrode layer is formed. The masking plate is a plate-shape member having an opening in a patterned shape. Then, an electrode layer is fanned on a whole surface of the base member. The electrode layer is formed on the masking plate in an area where the masking plate exists, and the electrode layer is formed directly on the base member in an area where no masking plate exists. Then, the masking plate is lifted up from the base member. Thus, only the electrode layer formed directly on the base member remains on the base member. Hereby, the electrode layer is patterned.

Further, the self-alignment is the following technique. In the self-alignment, patterning is performed first to a surface of a base member so as to form a layer to become a base. Then, plating or the like is performed so that an electrode layer is grown only on the base layer. Hereby, the electrode layer is patterned naturally.

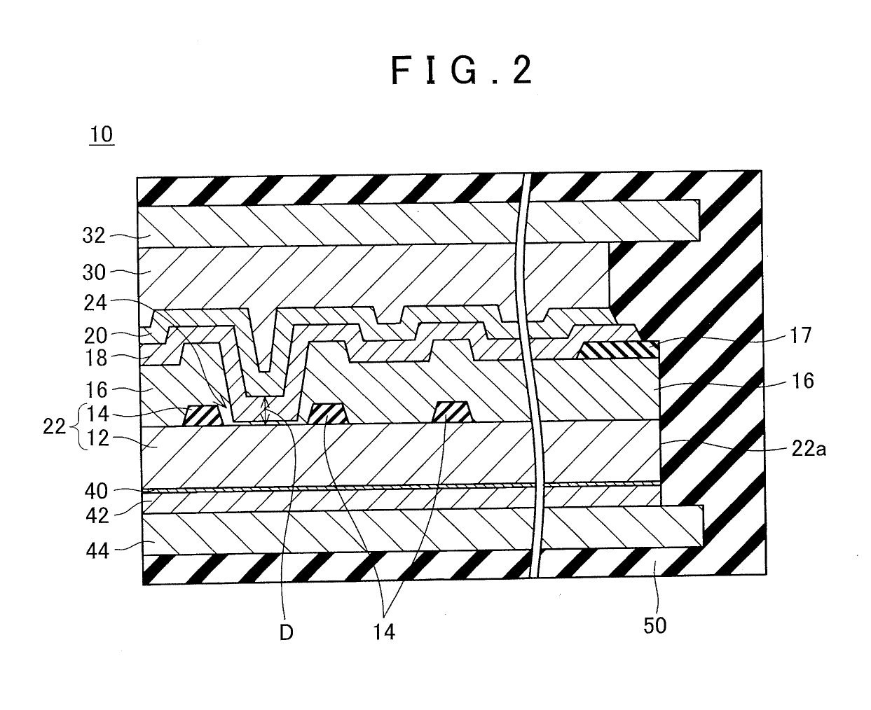

Note that, in Embodiment 1, the substrate-side electrode layer 16 is not formed in a part of the region 24, but the substrate-side electrode layer 16 may be formed entirely in the region 24. For example, as illustrated in FIG. 2, the substrate-side electrode layer 16 may include a portion, the portion having a relatively small thickness and being placed in the region 24. Even in such a case, if the region 24 between two insulating layers 14 is filled with the intermediate electrode layer 18, it is possible to prevent the front-side electrode layer 20 from getting into the region 24. Accordingly, even in such a configuration, it is possible to restrain a stress in the semiconductor device 10. Note that, in this case, if a distance D between the surface of the semiconductor layer 12 (that is, the substrate 22) and a top face of the intermediate electrode layer 18 is larger than a thickness of each of the insulating layers 14, it is possible to prevent the front-side electrode layer 20 from getting into the region 24.

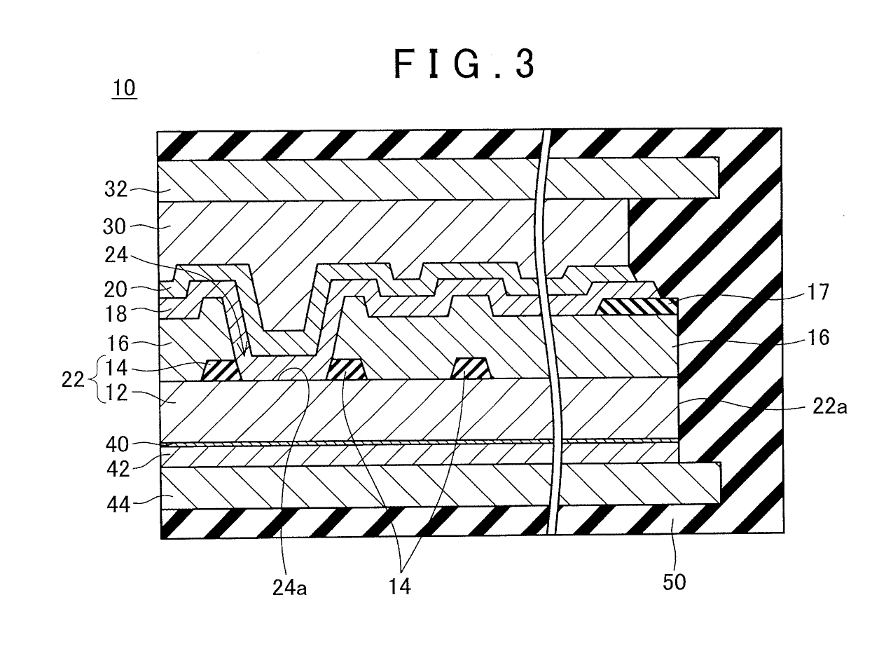

Further, in Embodiment 1 described above, the substrate-side electrode layer 16 is provided partially in the region 24 between two insulating layers 14. However, the substrate-side electrode layer 16 may not be provided in the region 24, as illustrated in FIG. 3. Even in such a case, it is possible to prevent the front-side electrode layer 20 from getting into the region 24 due to the intermediate electrode layer 18.

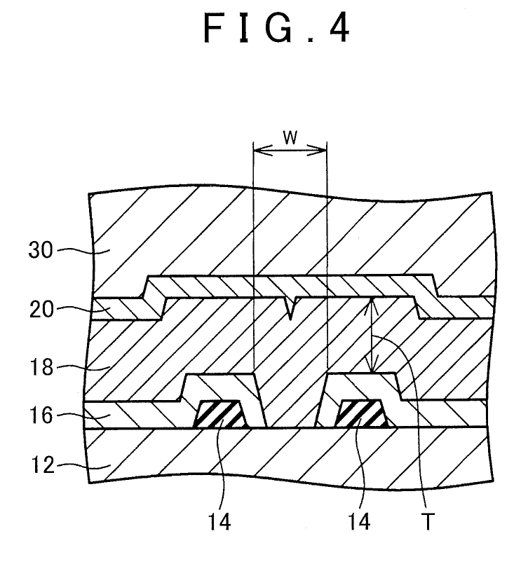

Note that, as illustrated in FIG. 4, a width W of a recessed portion of the substrate-side electrode layer 16 in the region 24 between the insulating layers 14 may be smaller than twice a thickness T of that part of the intermediate electrode layer 18 which is placed on the insulating layer 14. According to such a configuration, it is possible to fill the recessed portion of the substrate-side electrode layer 16 with the intermediate electrode layer 18 and to more easily manufacture the semiconductor device 10. That is, at the time when the intermediate electrode layer 18 is grown, the intermediate electrode layer 18 is grown with a generally even thickness on a surface of the recessed portion of the substrate-side electrode layer 16. Accordingly, if the intermediate electrode layer 18 is formed so as to have a thickness of half of the width W, it is possible to fill the recessed portion of the substrate-side electrode layer 16 with the intermediate electrode layer 18. On the other hand, in a case where the width W is very large, if the intermediate electrode layer 18 is not formed so as to have a thickness corresponding to a depth of the recessed portion of the substrate-side electrode layer 16, it is difficult to fill the recessed portion with the intermediate electrode layer 18. That is, if a relationship of W<2T is satisfied, it is possible to fill the recessed portion with the thin intermediate electrode layer 18. In view of this, according to such a configuration, it is possible to restrain a stress from the front-side electrode layer 20 from being applied to the insulating layers 14 and the semiconductor layer 12, and it is also possible to more efficiently manufacture the semiconductor device 10.

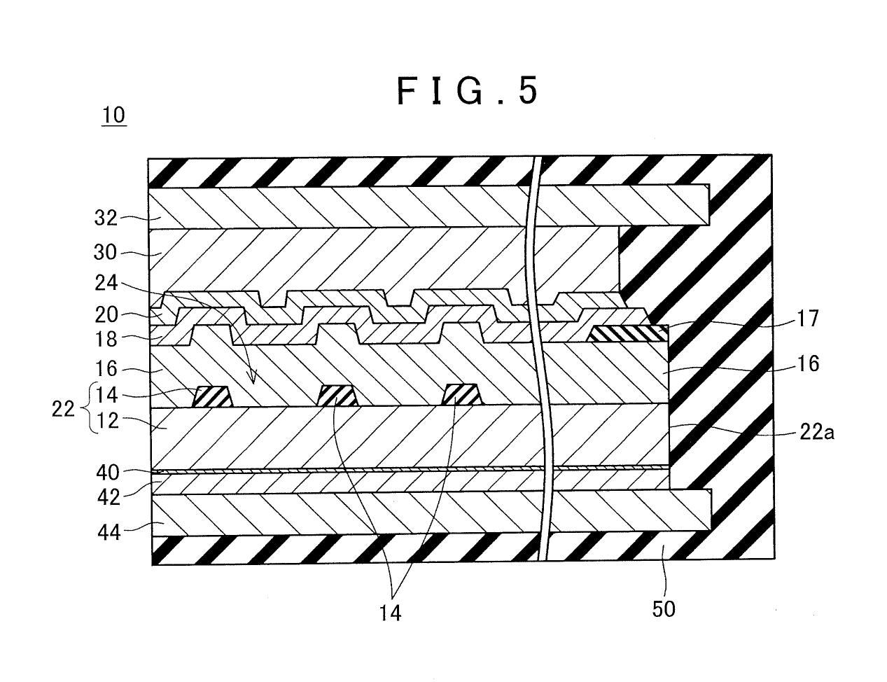

Further, as illustrated in FIG. 5, the region 24 between two insulating layers 14 may be filled with the substrate-side electrode layer 16. Even in such a configuration, it is possible to restrain a stress from the front-side electrode layer 20 from being applied to the insulating layers 14 and the semiconductor layer 12, due to the soft intermediate electrode layer 18.

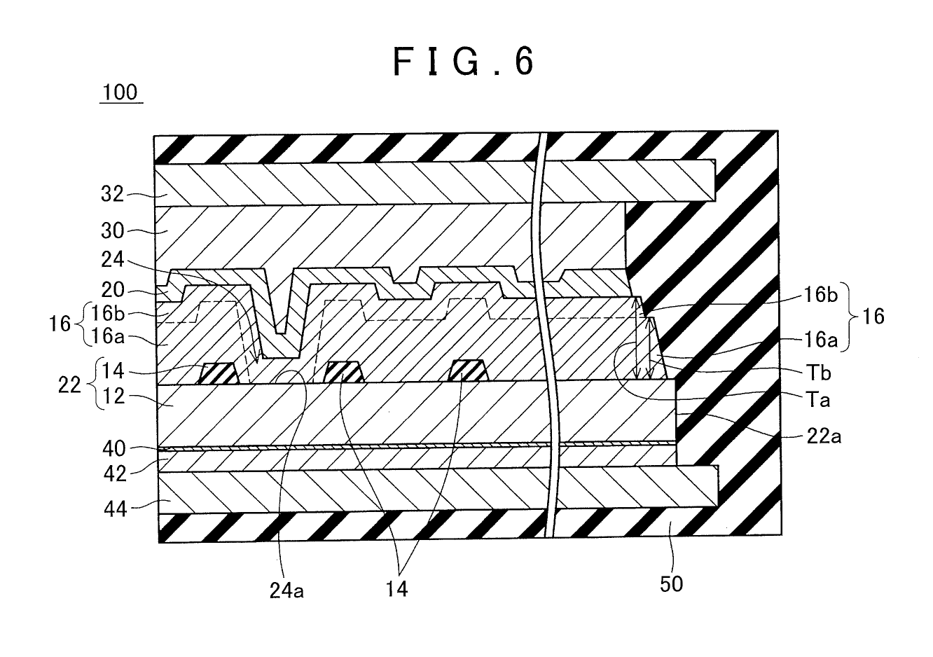

A semiconductor device 100 of Embodiment 2 illustrated in FIG. 6 includes a substrate-side electrode layer 16 made of Al, and a front-side electrode layer 20 made of Ni or Cu. Note that, as will be described in detail later, in the substrate-side electrode layer 16 illustrated in FIG. 6, a first layer 16a provided below a dotted line and a second layer 16b provided above the dotted line are formed in different steps. That is, it may be said that the semiconductor device 100 of Embodiment 2 is configured such that the substrate-side electrode layer 16 and the intermediate electrode layer 18 are made of the same material (a material having the same Young's modulus) in the semiconductor device 10 of Embodiment 1. A Young's modulus of the front-side electrode layer 20 is higher than a Young's modulus of the substrate-side electrode layer 16.

In the semiconductor device 100, a region 24 between two insulating layers 14 is filled with the substrate-side electrode layer 16, and no hard front-side electrode layer 20 exists in the region 24. This makes it possible to restrain a stress to be applied to the insulating layers 14 and a semiconductor layer 12 from the front-side electrode layer 20.

Next will be described a manufacturing method of the semiconductor device 100. First, a plurality of insulating layers 14 is formed on a surface of a semiconductor layer 12 by any method well known in the art. Then, a first layer 16a of a substrate-side electrode layer 16 is formed. That is, the first layer 16a is formed, and then patterning is performed to the first layer 16a. By performing the patterning, a region 24a where no first layer 16a exists may be formed intentionally within a region 24 between two insulating layers 14. Further, in a step of forming the first layer 16a, the region 24a may be formed unintentionally. After the first layer 16a is formed, a second layer 16b is formed by use of the same material as the first layer 16a on a surface of a substrate including the first layer 16a. That is, a second layer 16b is formed, and then patterning is performed to the second layer 16b. The second layer 16b is formed to be thicker than the insulating layers 14. Hereby, the second layer 16b is formed in the region 24a and on the first layer 16a. According to the above steps, the substrate-side electrode layer 16 is formed. As illustrated in FIG. 6, in the vicinity of an end 22a of the substrate 22, the second layer 16b is placed in a position farther from the end 22a than the first layer 16a. Because of this, in the vicinity of the end 22a, a first portion having a thickness Ta, and a second portion having a thickness Tb smaller than the thickness Ta are formed in the substrate-side electrode layer 16. The second portion having a smaller thickness is placed closer to the end 22a than the first portion. That is, a stepped structure is formed in that part of the substrate-side electrode layer 16 which is close to the end 22a. Then, a front-side electrode layer 20 is formed on the substrate-side electrode layer 16. Even in the region 24 between two insulating layers 14, the substrate-side electrode layer 16 is thicker than the insulating layers 14, so that the front-side electrode layer 20 does not get into the region 24 between two insulating layers 14. Hereby, a structure in which a high stress is hard to occur in the insulating layers 14 and the semiconductor layer 12 is obtained. After that, a back-surface electrode 40 is formed, and soldering to lead frames 32, 42 is performed. Then, a resin layer 50 is formed, and thus, the semiconductor device 100 is completed.

Note that, as described above, the first layer 16a and the second layer 16b of the substrate-side electrode layer 16 are formed in different steps. This restrains such a problem that a defect is formed in the same area in the first layer 16a and in the second layer 16b. Note that, in the step of forming the first layer 16a, any of spattering, deposition, plating, brush application, inkjet coating, and spray coating can be employed as a film forming method, for example. Further, in the step of forming the first layer 16a, any of photolithography, liftoff, masking, and self-alignment can be employed as a patterning method, for example. Also in the step of forming the second layer 16b, any one of the above film forming methods can be employed, and any one of the above patterning methods can be employed. Here, it is preferable that the step of forming the first layer 16a and the step of forming the second layer 16b employ different methods for at least either of the film forming method and the patterning method. This reduces such a possibility that regions where no electrode layer is formed are formed in the same area in the first layer 16a and the second layer 16b. Thus, according to the above manufacturing method, it is possible to more surely prevent the front-side electrode layer 20 from being formed in proximity to the insulating layers 14 and the semiconductor layer 12, similarly to Embodiment 1.

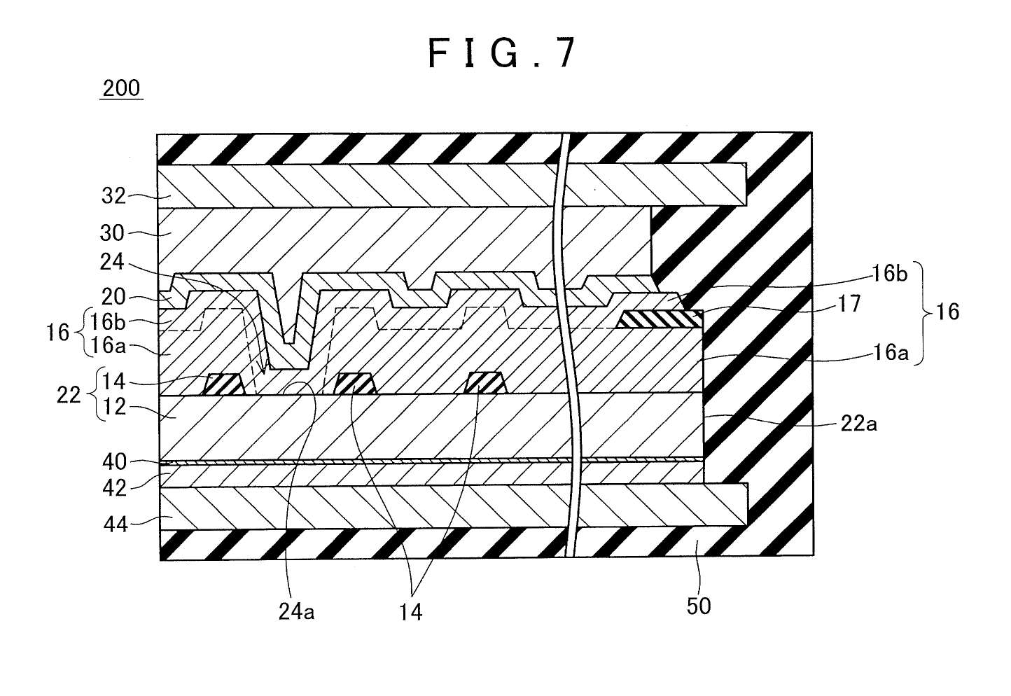

In a semiconductor device 200 of Embodiment 3 illustrated in FIG. 7, an insulating layer 17 is formed in the vicinity of an end 22a of a substrate 22. The other structure of the semiconductor device 200 of Embodiment 3 is generally the same as the semiconductor device 100 of Embodiment 2.

In the semiconductor device 200, a bottom face of the insulating layer 17 is covered with a first layer 16a, and a top face of the insulating layer 17 is covered with a second layer 16b. That is, the insulating layer 17 is sandwiched between the first layer 16a and the second layer 16b that are made of the same material. Since the material of electrode layers provided on the top and bottom faces of the insulating layer 17 is the same material (that is, a material having the same Young's modulus), a thermal stress to be applied to the insulating layer 17 is restrained in the semiconductor device 200 in comparison with a case where the electrode layers are made of different materials. Further, in the semiconductor device 200, similarly to the semiconductor device 100 of Embodiment 2, a stress to be applied to insulating layers 14 and a semiconductor layer 12 from a front-side electrode layer 20 is restrained.

The semiconductor device 200 of Embodiment 3 is manufactured by generally the same method as the semiconductor device 100 of Embodiment 2. Note that, a step of forming the insulating layer 17 on the first layer 16a is performed after the first layer 16a is formed. After the insulating layer 17 is formed, the second layer 16b is formed on the first layer 16a and the insulating layer 17. Accordingly, the insulating layer 17 is sandwiched between the first layer 16a and the second layer 16b. Also in the manufacturing method of Embodiment 3, it is preferable that a step of forming the first layer 16a and a step of forming the second layer 16b employ different methods for at least either of the film forming method and the patterning method. Hereby, it is possible to obtain the same effect as in Embodiment 2.

Note that, in Embodiment 2 and Embodiment 3, the first layer 16a can be regarded as a layer corresponding to the substrate-side electrode layer 16 of Embodiment 1, and the second layer 16b can be regarded as a layer corresponding to the intermediate electrode layer 18 of Embodiment 1. Accordingly, also in Embodiment 2 and Embodiment 3, the first layer 16a may be formed in the whole region 24 between two insulating layers 14 like FIG. 2 of Embodiment 1, and the first layer 16a may not be formed in the region 24 like FIG. 3. Further, a width W of a recessed portion of the first layer 16a may be smaller than twice a thickness T of that part of the second layer 16b which is placed on the insulating layer 14 like FIG. 4. Further, as illustrated in FIG. 5, the region 24 between two insulating layers 14 may be filled with the first layer 16a.

Further, in Embodiments 1 to 3, the insulating layer 14 constitutes the projection portion of the substrate 22. However, the projection portion may be formed of a semiconductor.

In the above, although specific embodiments of the present invention were detailed, these are only illustrations. In the present invention, various modifications and alterations of the specific embodiments illustrated above are included. The technical elements described in the present specification and the drawings can exhibit technical usefulness singularly or in various combinations thereof.

What is claimed is:

1. A semiconductor device comprising:
a substrate including a semiconductor layer and a projection portion, the projection portion being formed on a surface of the semiconductor layer;
a substrate-side electrode layer provided on the projection portion;
an intermediate electrode layer extending from on a part of the substrate-side electrode layer, which part of the substrate-side electrode layer is located on the projection portion, to just above a region of the substrate in which region the projection portion is not provided; and
a front-side electrode layer provided on a surface of the intermediate electrode layer, wherein
a Young's modulus E1 of the substrate-side electrode layer, a Young's modulus E2 of the intermediate electrode layer, and a Young's modulus E3 of the front-side electrode layer satisfy a relationship of E3>E1>E2.

2. The semiconductor device according to claim 1, wherein:
the intermediate electrode layer is provided in a lateral side of the projection portion; and
a distance between the surface of the semiconductor layer and the surface of the intermediate electrode layer provided in the lateral side of the projection portion is larger than a height of the projection portion from the surface of the semiconductor layer.

3. The semiconductor device according to claim 2, wherein:
a recessed portion of the substrate-side electrode layer is formed in the lateral side of the projection portion; and
a width of the recessed portion is smaller than twice a thickness of a part of the intermediate electrode layer, the part of the intermediate electrode layer being arranged just above the projection portion.

4. A semiconductor device comprising:
a substrate including a semiconductor layer and a projection portion, the projection portion being formed on a surface of the semiconductor layer;
a substrate-side electrode layer extending from on the projection portion to just above a region of the substrate in which region the projection portion is not provided; and
a front-side electrode layer provided on the substrate-side electrode layer and having a Young's modulus larger than a Young's modulus of the substrate-side electrode layer, wherein:
the substrate-side electrode layer includes a first portion and a second portion in an end of the substrate-side electrode layer in a surface direction of the substrate;
the first portion has a first thickness; and
the second portion has a second thickness smaller than the first thickness, and is provided outside the first portion in the surface direction.

5. A semiconductor device comprising:
a substrate including a semiconductor layer and a projection portion, the projection portion being formed on a surface of the semiconductor layer;
a substrate-side electrode layer extending from on the projection portion to just above a region of the substrate in which region the projection portion is not provided;
a front-side electrode layer provided on the substrate-side electrode layer and having a Young's modulus larger than a Young's modulus of the substrate-side electrode layer; and
an insulating layer, wherein a front surface of the insulating layer and a back surface of the insulating layer are covered with the substrate-side electrode layer.

6. A manufacturing method of a semiconductor device, the manufacturing method comprising:
forming a substrate-side electrode layer on a projection portion of a substrate, the substrate including a semiconductor layer and the projection portion, the projection portion being formed on a surface of the semiconductor layer;
forming an intermediate electrode layer that extends from on a part of the substrate-side electrode layer, which part of the substrate-side electrode layer is located on the projection portion, to just above a region of the substrate in which region the projection portion is not provided; and
forming a front-side electrode layer on the intermediate electrode layer, wherein
a Young's modulus of the front-side electrode layer is higher than a Young's modulus of the intermediate electrode layer and a Young's modulus of the substrate-side electrode layer.

7. The manufacturing method according to claim 6, wherein:
the Young's modulus of the substrate-side electrode layer is higher than the Young's modulus of the intermediate electrode layer.

8. The manufacturing method according to claim 6, wherein:
in the forming of the substrate-side electrode layer, any one of film forming methods consisting of spattering, deposition, plating, brush application, inkjet coating, and spray coating is employed as a film forming method of an electrode material;
in the forming of the substrate-side electrode layer, any one of patterning methods consisting of photolithography, liftoff, masking, and self-alignment is employed as a patterning method;
in the forming of the intermediate electrode layer, any one of the film forming methods and any one of the patterning methods are employed; and
the forming of the substrate-side electrode layer and the forming of the intermediate electrode layer are different from each other with respect to at least one of the film forming method and the patterning method.
